(19) United States
(12) Patent Application Publication
(10) Pub. No.: US 2018/0248098 A1
(43) Pub. Date: Aug. 30, 2018

(54) INTEGRATED DEVICE PACKAGE WITH THERMOELECTRIC GENERATOR DEVICE

(71) Applicant: ANALOG DEVICES, INC., Norwood, MA (US)

(72) Inventors: Jiawen Bai, Boston, MA (US); David Bolognia, Charlestown, MA (US)

(21) Appl. No.: 15/475,832

(22) Filed: Mar. 31, 2017

Related U.S. Application Data
(60) Provisional application No. 62/464,995, filed on Feb. 28, 2017.

(51) Int. Cl. H01L 35/30; H01L 35/10; G08C 17/00

(52) U.S. Cl. CPC H01L 35/30; G08C 2200/00; G08C 17/00; H01L 35/10

(57) ABSTRACT

An integrated device package can include a package substrate and a thermoelectric generator (“TEG”) device electrically connected to the package substrate. The TEG device can be configured to convert thermal energy to electrical current. A magnet can be disposed over a bottom side of the TEG device. The magnet can be configured to connect to a heat source and to define a thermally conductive pathway between the heat source and the TEG device. A heat sink can be attached to a top side of the TEG device.

### BACKGROUND

### Field

The field relates to integrated device packages, and in particular, to integrated device packages that include a thermoelectric generator (TEG) device.

### Description of the Related Art

Integrated device packages can be used in a variety of larger electronic systems to provide sensors, transducers, processors, memory devices, or other types of devices for use in a variety of environments. In some environments, it may be challenging to provide electrical power and/or electrical communication between the integrated device package (or the larger electronic system) and an external device disposed in another environment or location. For example, in some systems, it may be economically or technically inefficient or physically challenging to provide electrical power or communications lines between the integrated device package and the external device. Use of a battery for powering such devices can result in critical downtime for operation of the packaged device between depletion and recharging or replacement of the battery. Accordingly, there remains a continuing need for improved integrated device packages for use in different environments.

### SUMMARY

In one embodiment, an integrated device package is disclosed. The integrated device package can include a package substrate and a thermoelectric generator (“TEG”) device electrically connected to the package substrate, the TEG device configured to convert thermal energy to electrical current. A magnet can be disposed over a front side of the TEG device, the magnet configured to connect to a heat source and to define a thermally conductive pathway between the heat source and the TEG device.

In another embodiment, integrated device package can include a package substrate comprising an aperture and a thermoelectric generator (“TEG”) device positioned in the aperture and electrically connected to the package substrate, the TEG device configured to convert thermal energy to electrical current. A thermally conductive element can be disposed over a first side of the TEG device, the thermally conductive element configured to define a thermally conductive pathway between a heat source and the TEG device.

In another embodiment, an integrated device package can include a first thermally conductive element and a second thermally conductive element. The package can include a package substrate disposed between the first and the second thermally conductive elements. A thermoelectric generator (“TEG”) device can be disposed between the first and second thermally conductive elements and electrically connected to the package substrate. The TEG device can be configured to generate electricity from thermal energy based on a temperature difference between the first and second thermally conductive elements

Details of one or more implementations of the subject matter described in this specification are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

Specific implementations of the invention will now be described with reference to the following drawings, which are provided by way of example, and not limitation.

FIG. 1 is a schematic side sectional view of an integrated device package having a thermoelectric generator device and being connected to a heat source, according to various embodiments.

FIG. 2 is a schematic, enlarged front sectional view of the integrated device package shown in FIG. 1.

FIG. 3 is a schematic, isometric, exploded view of portions of the integrated device package shown in FIGS. 1 and 2.

FIG. 4 is a schematic side elevational view of the integrated device package shown in FIGS. 1-3.

FIG. 5 is a top plan view of the integrated device package shown in FIGS. 1-4.

FIG. 6 is a schematic side sectional view of an integrated device package connected to a plurality of heat sources, according to another embodiment.

FIG. 7 is a schematic front and bottom isometric view of the integrated device package connected to a band configured to mount the package to a heat source.

FIG. 8 is a schematic side sectional view of an integrated device package having a thermoelectric generator device and being connected to a heat source, according to another embodiment.

FIG. 9 is a schematic, enlarged front sectional view of the integrated device package shown in FIG. 8.

FIG. 10 is a schematic, isometric, exploded and inverted view of portions of the integrated device package shown in FIGS. 8 and 9.

FIG. 11 is a schematic side elevational view of the integrated device package shown in FIGS. 8-10.

FIG. 12 is a top plan view of the integrated device package shown in FIGS. 8-11.

FIG. 13 is a schematic side sectional view of an integrated device package connected to a plurality of heat sources, according to another embodiment.

FIG. 14 is a schematic front and bottom isometric view of the integrated device package connected to a band configured to mount the package to a heat source.

### DETAILED DESCRIPTION

Various embodiments disclosed herein relate to integrated device packages that include one or more thermoelectric generator (“TEG”) devices. A TEG device generates electrical current from thermal energy based on a temperature difference (ΔT) between a first side of the TEG device (e.g., a hot side of the TEG device) and a second side of the TEG device (e.g., a cold side of the TEG device). In various TEG devices, the greater the temperature difference ΔT, the greater amount of electrical energy the TEG may generate. The embodiments disclosed herein can utilize a TEG device in connection with a high temperature heat source such as a steam pipe, a radioactive element (such as those used in space probes), a tailpipe or engine of an automobile, etc. The embodiments disclosed herein can be configured to monitor vibration of steam pipes or boiler walls in a power plant, to monitor vibration of water pumps in a water treatment plant, and any other suitable sensing application. One challenge to manufacturing an efficient thermoelectric generator system is to provide high thermal conductivity between the first and second sides of the TEG device (e.g., between the hot and cold sides of the TEG), as well as a large ΔT throughout the operation of the system. Various embodiments disclosed herein provide an integrated device package with a TEG device that can operate at a wide range of temperature differences ΔT, and may be particularly beneficial for systems used with relatively small temperature difference between first and second sides of the TEG device. The embodiments disclosed herein can also provide a very low thermal resistance so as to reduce thermal losses in the system.

The embodiments disclosed herein may be beneficial for electronic systems having sensors that operate for a relatively long duration, and/or for multiple series of measurements without replacement. The embodiments disclosed herein may also be particularly beneficial for systems used in remote and/or inaccessible places where an electrical power source may not be easily reachable and/or where replacement of an electricity source may be difficult. The integrated device packages disclosed herein can be mechanically and thermally connected to a support structure, which can act as a first heat source for the package. For example, the support structure or heat source (such as a steam pipe) can have a relatively high temperature so as to act as a heat source for the integrated device package and TEG device. Thermal energy from the support structure or heat source can be converted to electrical current by the TEG device. The electrical current generated by the TEG device can be supplied to provide electrical power to one or more integrated device dies of the package. For example, in some embodiments, the electrical current can supply power to a sensor die, a processor die configured to process signals (e.g., signals transduced by the sensor die), a communications die (e.g., a transmitter configured to wirelessly transmit wireless signals to an external device), a memory die, and/or any other suitable type of integrated device die, either directly or indirectly through a battery that the TEG device recharges. In some embodiments, the integrated device dies can monitor the operational environment, including, e.g., the temperature, humidity, etc. of a steam pipe to which the package is attached.

Beneficially, the integrated device package can generate electrical power sufficient to power the operation of the integrated device package, without requiring connection to an external power supply. Moreover, the integrated device package can electrically communicate with an external device (such as a computing device) over a wireless network by one or more communications dies in the package, which also may be powered, directly or indirectly, by the TEG device. Thus, the embodiments disclosed herein enable sensing, processing, and/or communications capabilities in remote environments without requiring a connection to an external power source.

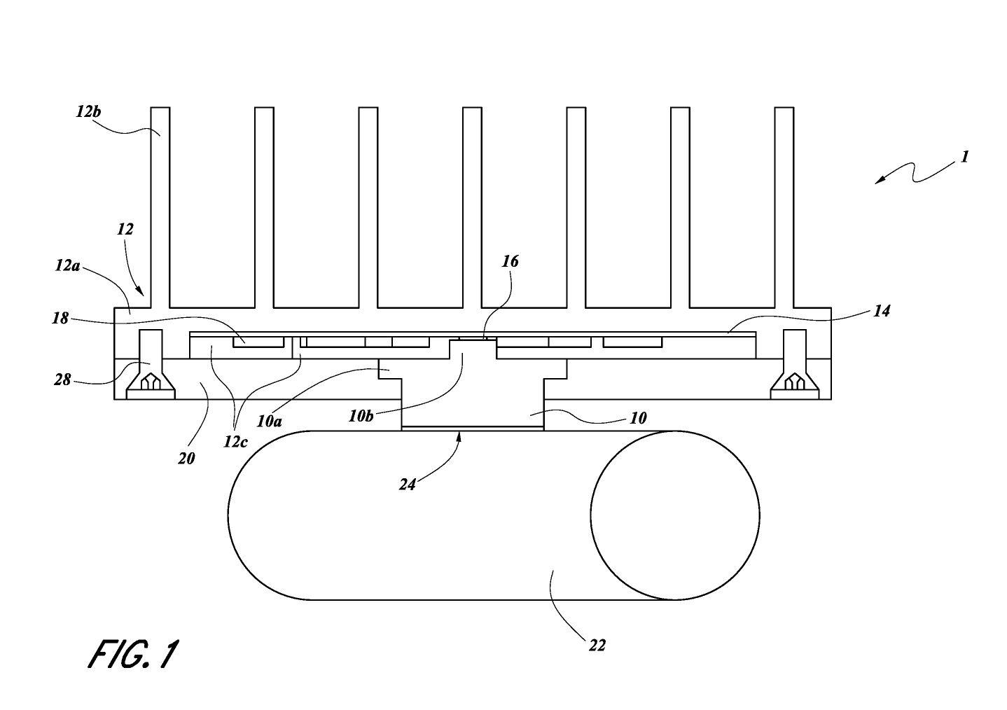

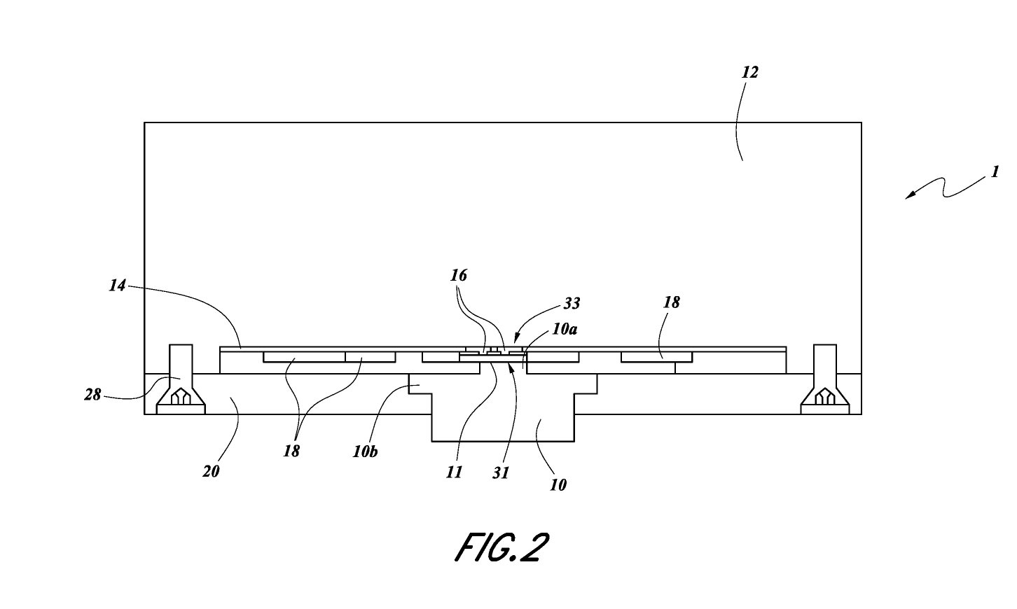

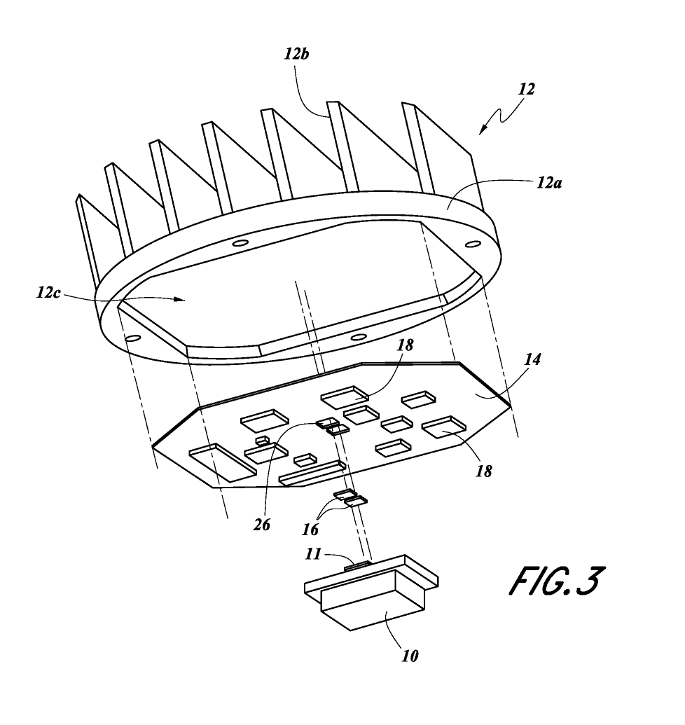

FIG. 1 is a schematic side sectional view of an integrated device package 1 having a thermoelectric generator (TEG) device 16 and being connected to a support structure such as the illustrated heat source 22, according to various embodiments. FIG. 2 is a schematic, enlarged front sectional view of the integrated device package 1 shown in FIG. 1, without the heat source 22. FIG. 3 is a schematic, perspective exploded view of portions of the integrated device package 1 shown in FIGS. 1 and 2. As shown in FIG. 1, the package can include a first thermally conductive element 10, a second thermally conductive element 12, a packaging substrate 14, the TEG device 16, a plurality of electrical components 18 (such as integrated device dies configured for sensing, processing, memory and/or communication, passive electronic components, batteries, etc.), and a housing 20. As shown in FIGS. 1 and 2, the substrate 14, the electrical components 18, and the TEG device 16 can be disposed vertically between the first and second thermally conductive elements 10, 12. Any suitable number of TEG devices 16 can be used in the disclosed embodiments. For example, in the embodiment of FIGS. 1-3, a plurality of (e.g., two) TEG devices 16 are illustrated. The first thermally conductive element 10 and/or the second thermally conductive element 12 can comprise any suitable thermally conductive material, for example metals such as iron, nickel, cobalt, aluminum, or copper, and alloys of these materials.

The substrate 14 can comprise any suitable type of package substrate. In the illustrated embodiment, the substrate 14 comprises a laminate substrate (e.g., a printed circuit board), but in other embodiments, the substrate 14 can comprise a leadframe, a molded leadframe, a ceramic substrate, a polymer substrate, etc. As shown in FIG. 3, the substrate 14 can include one or a plurality of apertures 26 in which the TEG devices 16 can be positioned. The apertures 26 can enable a first side 31 of the TEG device 16 to thermally couple to the first thermally conductive element 10 and a second side 33 of the TEG device 16 to thermally couple to the second thermally conductive element 12. Thus, in the illustrated embodiment, the TEG device 16 may not be mechanically supported by the substrate 14. Rather, as explained herein, the second side 33 of the TEG device 16 can be connected to the second thermally conductive element 12, for example, by a thermally conductive adhesive, e.g., a thermal die attach epoxy, or by otherwise attaching the TEG device 16 to the second thermally conductive element 12 with a thermal gap pad, thermal grease or other thermal interface material (TIM) there between. The TEG device 16 can be electrically connected to corresponding contact pads of the substrate 14 in any suitable manner. For example, in some embodiments, the TEG device 16 can be wire bonded to the contact pads of the substrate 14 after adhering the substrate 14 to the thermally conductive element 10 or 12 that initially supports the TEG device 16. In another embodiment, terminals of the TEG device may connect with traces on the substrate 14 by way of spring-loaded contacts.

In some embodiments, the second thermally conductive element 12 can comprise, or can act as, a heat sink. As shown in FIG. 1, for example, the second thermally conductive element 12 can comprise a lateral conductive plate 12a and a plurality of fins 12b extending vertically outward from the lateral conductive plate 12. The fins 12b can facilitate the transfer of heat from the package 1 to the outside environs. As explained herein, in some embodiments, the second element 12 may not comprise a finned heat sink, but may, for example, comprise or be coupled with a second heat source or support structure that has a different temperature from the heat source 22. In some embodiments, the second element 12 can be omitted and the second side 33 of the TEG device 16 can be exposed to the outside environs. In various embodiments, the second element 12 can be detachable and replaced by a user to meet a desired operational characteristic. The second element 12 can comprise any suitable thermally conductive material, such as cast or molded steel, aluminum, copper, etc.

As shown in FIG. 3, the second thermally conductive element 12 can comprise a cavity 12c sized and shaped to receive the substrate 14, electrical components 18, and the TEG device(s) 16. The cavity 12c can be sized and configured so as to accommodate the electrical components 18 and/or the substrate 14. The portion of the lateral conductive plate 12a that defines the floor of the cavity 12c can be adhered to the second (e.g., top) side 33 (FIG. 2) of the TEG device 16 by way of a thermally conductive adhesive. The housing 20 can be provided to mechanically secure or couple the first thermally conductive element 10 to the second thermally conductive element 12 and to protect the electrical component(s) 18. For example, one or more fasteners 28 (e.g., screws, bolts, etc.) can mechanically connect the housing 20 to the second thermally conductive element 12. The fasteners 28 can enable easy assembly and/or disassembly by a user, particularly for ready replacement of the second element 12 with alternative structures for different applications. As shown in FIGS. 1 and 2, a projecting portion 10a of the first element 10 can extend through an opening to thermally couple with the TEG device 16. An outwardly-extending flange portion 10b of the first element 10 can extend generally parallel to the housing 20. The housing 20 can bear against or otherwise engage the flange portion 10b to secure the first element 10 to the package 1 and position the first element 10 relative to the TEG device 16 for efficient heat transfer from the first element 10 to the TEG device 16. The housing 20 can surround the first element 10 to secure the first element 10 within the package 1.

As shown in FIGS. 2 and 3, the first side 31 of the TEG device 16 can thermally couple to the first thermally conductive element 10 along a thermally conductive pathway. For example, the first (e.g., bottom) side 31 of the TEG device 16 can thermally couple to the first element 10 by way of a thermal interface element 11 (such as a thermally conductive gap pad or TIM) disposed between the first element 10 and the TEG device 16. In various embodiments, the thermal interface element 11 can comprise a gap pad (e.g., a soft dielectric film) or a TIM (which can comprise a metal carrier, grease, etc.). The first thermally conductive element 10 may have different temperatures during use (e.g., different temperatures at various operating conditions and environmental conditions), which may cause expansion and/or contraction of the first thermally conductive element 10. In addition, vibrations and/or other movements of the heat source 22 may be transferred to the TEG device 16 and substrate 14 by way of the first element 10. The transferred vibrations and/or movements may induce mechanical stress in the TEG device 16, which may damage the TEG 16 and/or may reduce the thermal conductivity of the TEG 16 and/or the first element 10.

The thermal interface element 11 may comprise a material configured to reduce or eliminate the stresses transmitted to the TEG device 16 (e.g., to the first side 31) and/or the first element 10, by providing the thermal interface element 11 as a sufficiently compliant buffer material to absorb expansion and/or contraction of the first element 10 relative to the TEG device 16, and by absorbing vibrations. In some embodiments, the thermal interface element 11 may comprise any suitable flexible or compliant material that is thermally conductive, such as an amine epoxy, amide epoxy, cycloaliphatic epoxy, amine adduct epoxy or any other suitable materials for the operational environment. In various embodiments, the thermal interface element 11 can comprise a thermal pad, a thermal grease, etc. The thermal interface element 11 can thereby enable the first thermally conductive element 10 to mechanically float over the TEG device 16 while providing a low thermal resistance pathway to the TEG device 16.

The TEG device 16 can generate electrical current based on a temperature difference ΔT between the first (e.g., bottom) side 31 of the TEG device 16 and the second (e.g., top) side 33 of the TEG device 16 opposite the first side 31. In various embodiments, the TEG device 16 can comprise a multi-layered semiconductor die that creates electrical current in the presence of a thermal gradient across the layers. In some embodiments, the TEG device 16 can comprise a microelectromechanical systems (MEMS) die, but other types of TEG devices may be used. In various embodiments, the TEG device 16 can comprise a TEG die including an integrated single chip thermoelectric energy harvester that comprises a plurality of electrically connected n-type and p-type thermoelectric element. In some embodiments, the TEG device 16 can convert thermal energy to electricity for temperature differences ΔT of at least 5° C., at least 10° C., or at least 15° C. The TEG device 16 can generate electrical current at an electrical power level that is in a range of 0.00001% to 0.1% of a thermal power level provided to the TEG device 16, or in a range of 0.0001 to 0.1% of the thermal power level. The TEG device 16 may generate 25 microwatts to 150 microwatts per 10° C. in temperature difference ΔT. For example, at a temperature difference ΔT of about 10° C., 1 W of thermal power supplied to the TEG device 16 can generate about 0.1 mW of electrical power in some arrangements. For additional examples of such a TEG, the following reference is hereby incorporated by reference herein in its entirety and for all purposes: U.S. Patent Publication No. 2014/0246066 A1, entitled “WAFER SCALE THERMOELECTRIC ENERGY HARVESTER,” published Sep. 4, 2014. As shown in FIGS. 1-3, a plurality of (e.g., two) TEG devices 16 can be disposed in corresponding apertures 26 in parallel with one another. Utilizing multiple TEG devices 16 may provide increased electrical power output as compared with packages that use a single TEG device. In other embodiments, however, the package 1 can include a single TEG device, or more than two TEG devices. The TEG device 16 can be made from any suitable material, such as bismuth telluride, lead telluride, calcium manganese oxide, silicon and/or combinations thereof, depending on the operational environment. As explained herein, the TEG device 16, which is electrically connected to the substrate 14 by way of, e.g., wire bonds or spring-loaded contacts (not shown), can supply the generated electricity to the electrical components 18 on the substrate 14, directly or indirectly by way of a rechargeable battery.

The first thermally conductive element 10 can contact the heat source 22 (which may be outside the package or electronic device, such as a pipe carrying hot fluid) along a first thermal interface surface 24 to transfer first thermal energy between the heat source 22 and the first side 31 of the TEG device 16, such that the first element 10 defines a thermally conductive pathway between the first heat source 22 and the first side 31 of the TEG device 16. The first element 10 may comprise any thermally conductive material that efficiently conducts heat, such as iron, copper, tungsten, etc. In some embodiments, e.g., if a delay in heat transfer is desired, lower thermally conductive materials may be used. In other arrangements, the package can comprise one or more energy storage devices (such as a battery) to store electrical energy generated by the TEG device. In the illustrated embodiment, the first thermally conductive element 10 comprises a magnetic material, or magnet, such that the thermally conductive element 10 can be directly mechanically and thermally connected to the heat source 22. Advantageously, using a magnetic, thermally conductive material for the first element 10 can enable the first element 10 to act as both a thermally conductive pathway and a mechanical connector for attaching the package 1 to the external heat source 22. Such an arrangement can simplify the design of the package 1, reduce the overall size of the package 1, and/or increase the efficiency of heat conductivity between the first thermal interface surface 24 and the first side 31 of the TEG device 16.

As explained above, the second thermally conductive element 12 can connect to the second side 33 of the TEG device 16. The second side 33 of the TEG device 16 and the second thermally conductive element 12 can define a second thermal pathway between the TEG device 16 and the outside environs (e.g., by way of the fins 12b and corresponding air gaps therebetween). The resulting temperature difference ΔT between the first and second thermally conductive elements 10, 12 can create a thermal gradient across the TEG device 16 sufficient to generate electrical current.

The plurality of electrical components 18 can include one or more of a sensor die, a wireless communications die (e.g., a wireless transmitter die and/or receiver die), a processor die or microcontroller, a memory die, and other components suitable for the purpose of operating the package 1. The electrical current generated by the TEG device 16 can be transmitted to the substrate 14 (e.g., by way of bonding wires) and to the electrical components 18 by way of conductive traces of the substrate 14. For example, in some embodiments, the package 1 can include sensor dies, such as one or more of temperature sensors, optical sensors, pressure sensors, humidity or moisture sensors, and/or motion sensors. The package 1 can also include a processor or microcontroller die to process signals transduced by the sensor dies and a communications die to wirelessly transmit and/or receive processed data to and/or from an external computing device. The package 1 can be used in a variety of operational environments. For example, the first thermally conductive element 10 of the package 1 can be attached to a steam pipe, or to a tailpipe of an automobile, to measure various parameters of these systems. The second thermally conductive element 12 can be exposed to ambient air. The TEG device 16 can generate electrical current based on the temperature difference ΔT between the steam pipe or tailpipe and ambient air. The package 1 can thereby provide electrical power to the electrical components 18, directly or indirectly by way of a battery, without requiring an external power source.

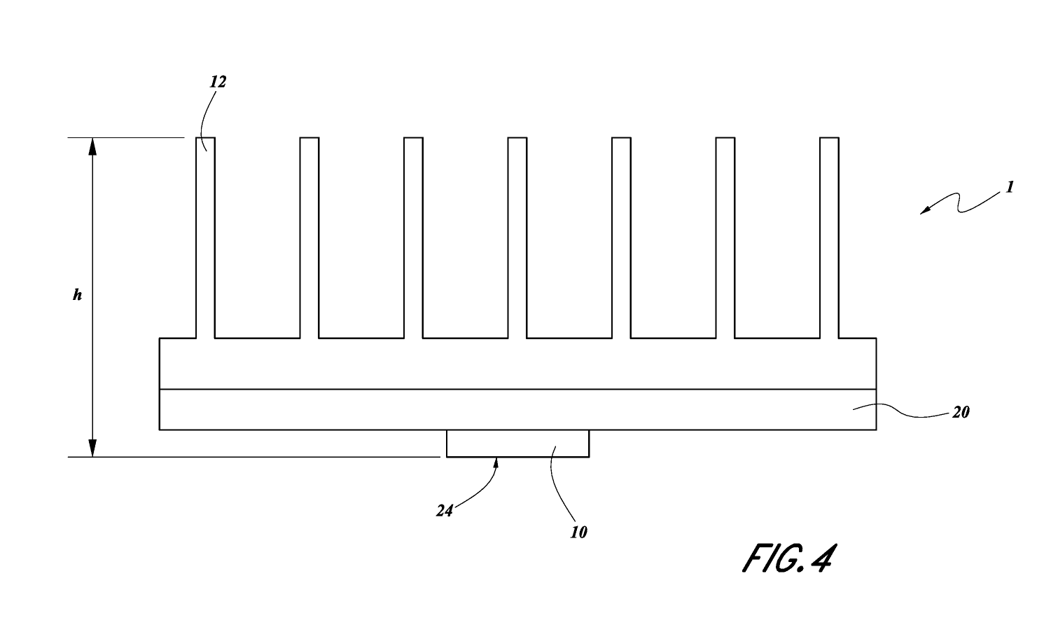

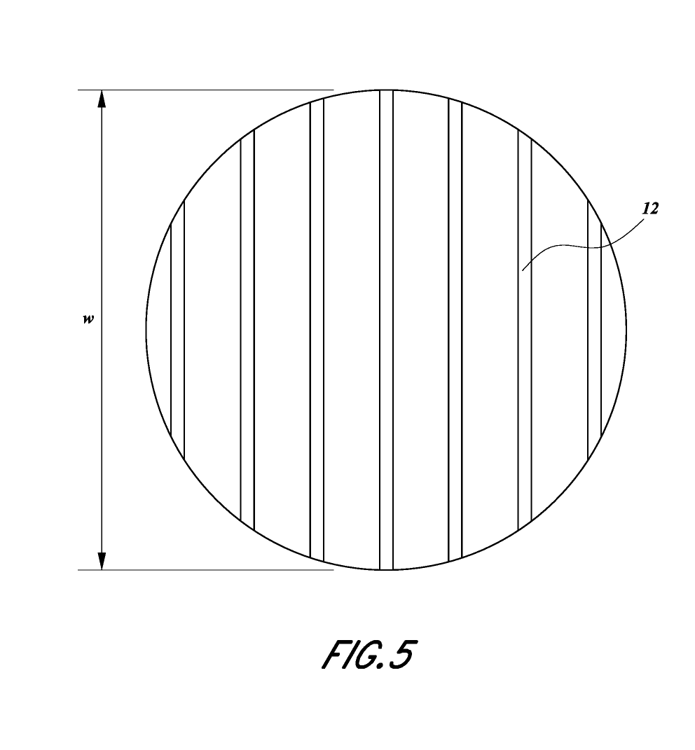

FIG. 4 is a schematic side view of the integrated device package 1 shown in FIGS. 1-3. FIG. 5 is a top plan view of the integrated device package 1 shown in FIGS. 1-4. Unless otherwise noted, the components of FIGS. 4-5 may be the same as or generally similar to like-numbered components of FIGS. 1-3. As shown in FIG. 4, the package 1 can have a height h defined by a maximum vertical dimension between the first thermal interface surface 24 and a top edge of the fins 12b. The height h may be less than 40 mm, e.g., in a range of 10 mm to 40 mm or in a range of 25 mm to 35 mm. As shown in FIG. 5, the package 1 can have a width w defined by the widest lateral dimension of the package 1 as seen from a rear plan view. The width w can be less than 100 mm, e.g., in a range of 35 mm to 100 mm or in a range of 55 mm to 80 mm. Beneficially, the package 1 disclosed herein can have a low vertical profile and a small lateral footprint, particularly for the functionality that can be achieved by the package without external power supplies or the need frequent battery replacement.

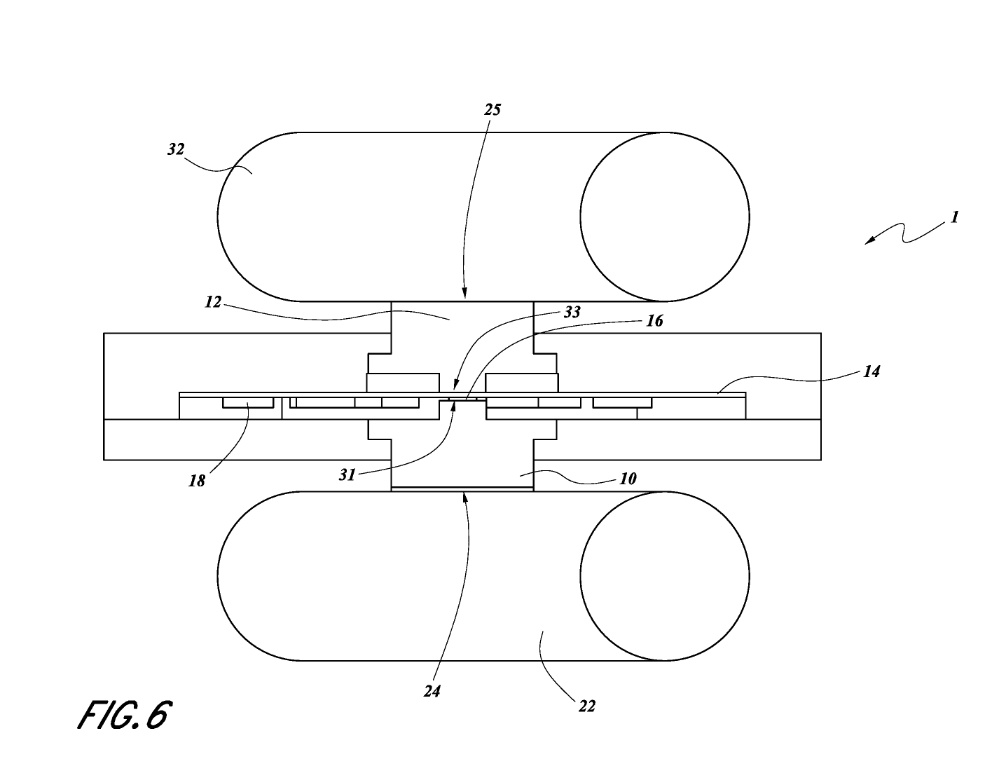

FIG. 6 is a schematic side sectional view of an integrated device package 1 connected to a plurality of heat sources 22, 32, according to another embodiment. Unless otherwise noted, the components of FIG. 6 may be the same as or generally similar to like-numbered components of FIGS. 1-5. By way of comparison, in the embodiment of FIG. 1, the first thermally conductive element 10 thermally couples to the heat source 22, and the second thermally conductive element 12 is exposed to the ambient environment. Unlike FIG. 1, in FIG. 6, the second thermally conductive element 12 is thermally coupled to a second heat source 32, which has a temperature from that of the heat source 22. In the embodiment of FIG. 6, the first and second thermally conductive elements 10, 12 can comprise a thermally conductive, magnetic material. As explained above, using a magnetic material for the elements 10, 12 can enable the package 1 to mechanically attach to the respective heat sources 22, 32 while providing efficient heat transfer to the TEG device 16.

In some embodiments, the heat source 22 can comprise a hot steam pipe and the second heat source 32 can comprise a cold water pipe. Accordingly, one of the so-called “heat sources” is in fact cold compared to the other. The first element 10 transfers heat from the first heat source 22 to the first side 31 of the TEG 16. The second element 12 similarly transfers heat from the second side 33 of the TEG 16 to a second thermal interface surface 25 between the second element 12 and the second heat source 32. The temperature difference ΔT between the first side 31 and the second side 33 of the TEG device 16 can generate electrical current to provide power to the electrical components 18 on the substrate 14.

It should be appreciated that the package 1 can be connected to any suitable device(s) that create a thermal gradient (e.g., a temperature difference ΔT) across the TEG device 16. In some embodiments, as in FIG. 1, the first thermally conductive element 10 can thermally connect to a support structure or heat source at a first temperature, and the second thermally conductive element 12 can be exposed to ambient air. In some embodiments, the first temperature can be greater than (e.g., at least 10° C. greater than) the second temperature. For example, the heat source 22 can comprise a steam pipe that is at a higher temperature than ambient air. In other arrangements, the package 1 can be integrated into wearable apparel (such as a ski hat or helmet), with the first thermally conductive element 10 thermally coupled to the user's body serving as the heat source 22 and the second thermally conductive element 12 exposed to ambient air. During winter, the temperature difference between the user's body and the ambient air may be sufficiently large so as to generate current for powering a variety of electronic devices. In still other embodiments, the ambient environment may be warmer than the heat source 22 such that heat flow is from the ambient environment to the so-called “heat source.”

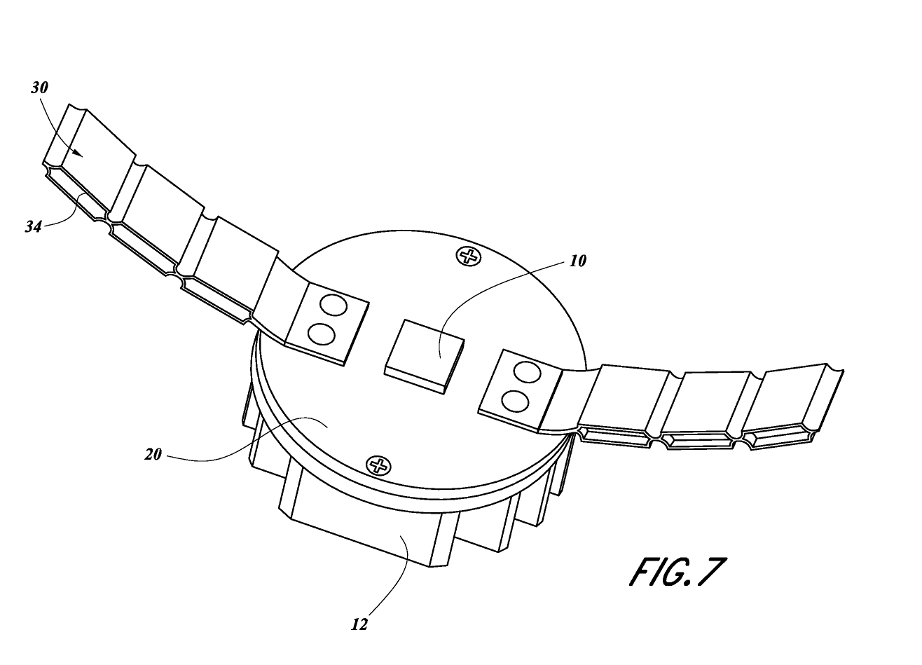

FIG. 7 is a schematic front and bottom isometric view of the integrated device package 1 having a band 30 attached to the housing 20. The band 30 (e.g., an attachment mechanism) can be sufficiently flexible so as to wrap at least a portion of the heat source 22, and can be configured in a manner that facilitates attachment of the package 1 to the heat source 22. For example, in the illustrated embodiment the band includes a plurality of magnets 34 to connect the package 1 to the heat source 22. The embodiment of FIG. 7 can therefore enable the user to easily attach the package 1 to the heat source 22, without requiring any external cables or wires to provide electrical power or communication to the package 1. In other embodiments, the band 30 can include an adhesive in addition to, or instead of, the magnets 34 to connect the band 30 to the heat source 22. Moreover, although the embodiments described herein are in the context of a tubular device such as a steam pipe, it should be appreciated that the band 30 and packages 1 can be configured to attach to any suitable support structure or heat source, including flat or curved support structures. Moreover, although an attachment mechanism comprising a band 30 is illustrated herein, it should be appreciated that other types of attachment mechanisms can be used to mechanically connect the package 1 to the heat source 22 (and/or heat source 32).

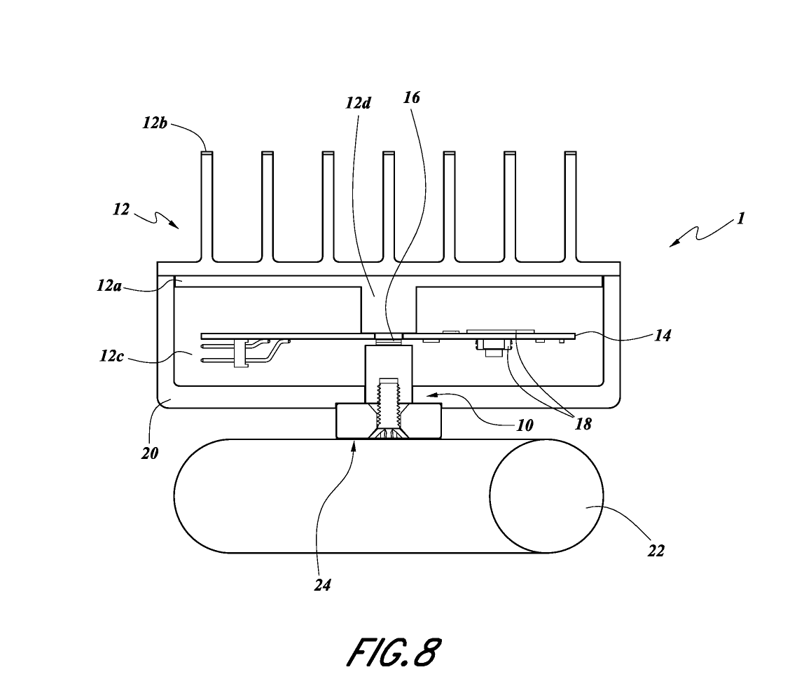

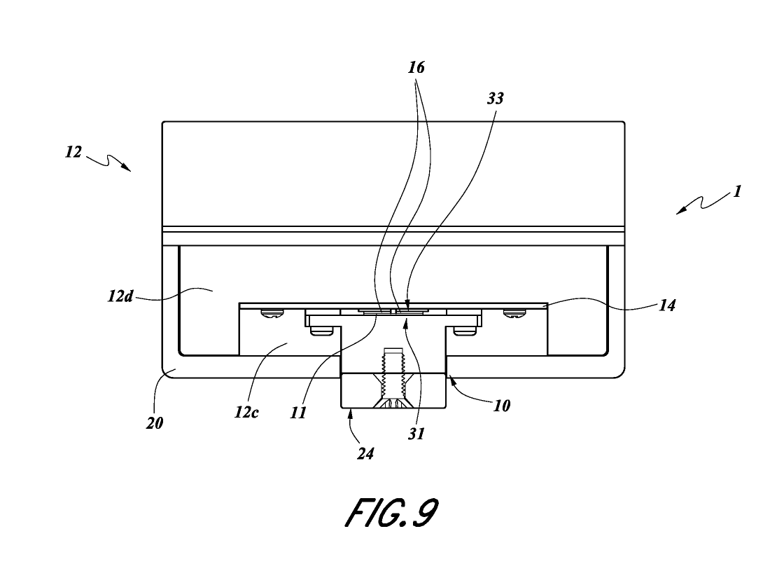

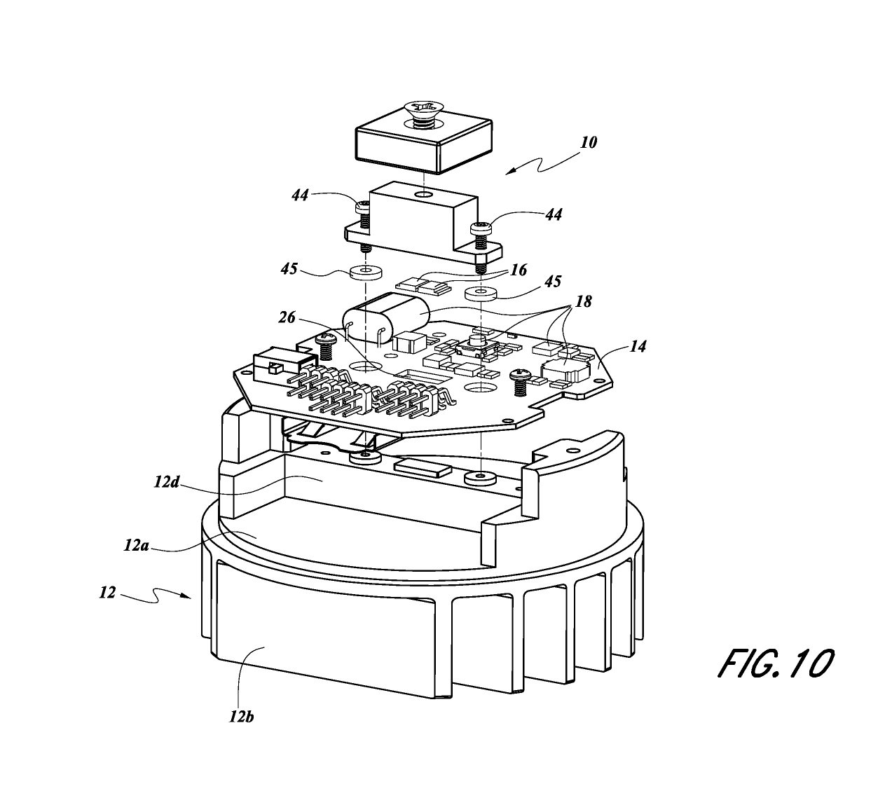

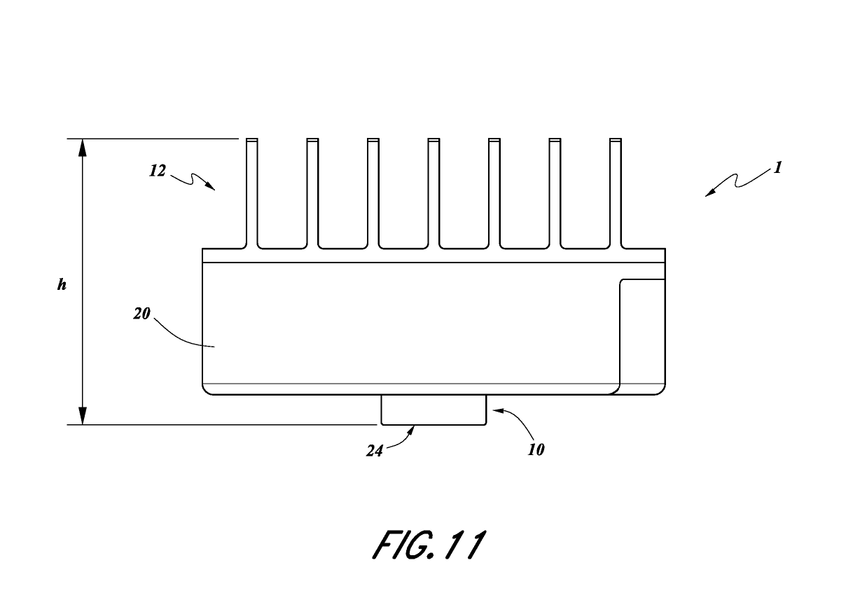

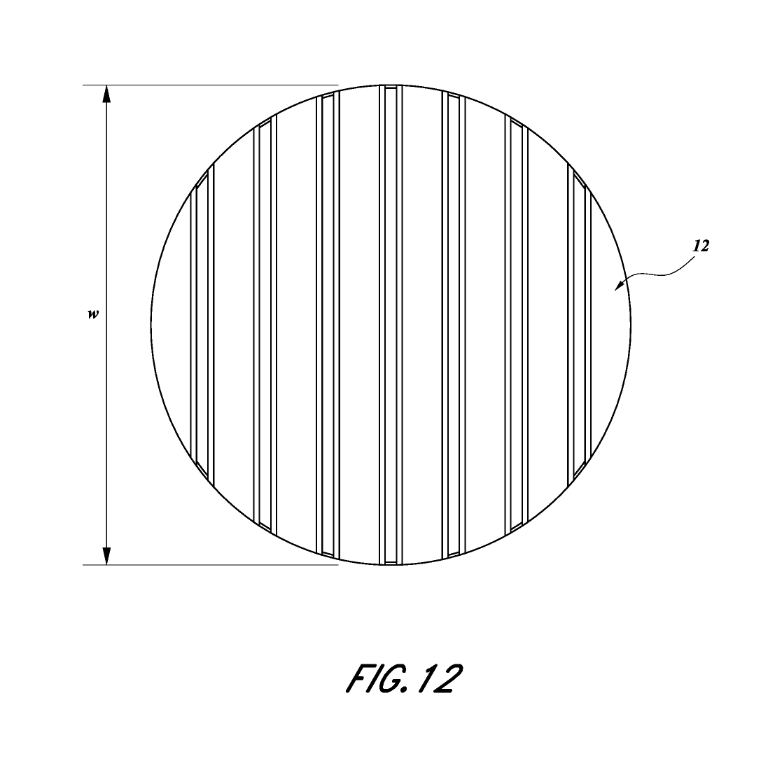

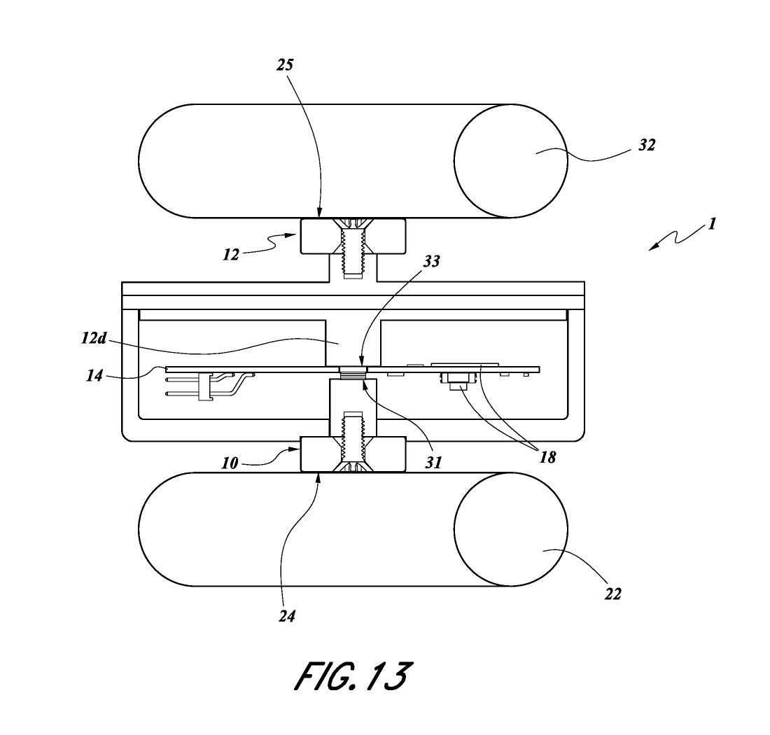

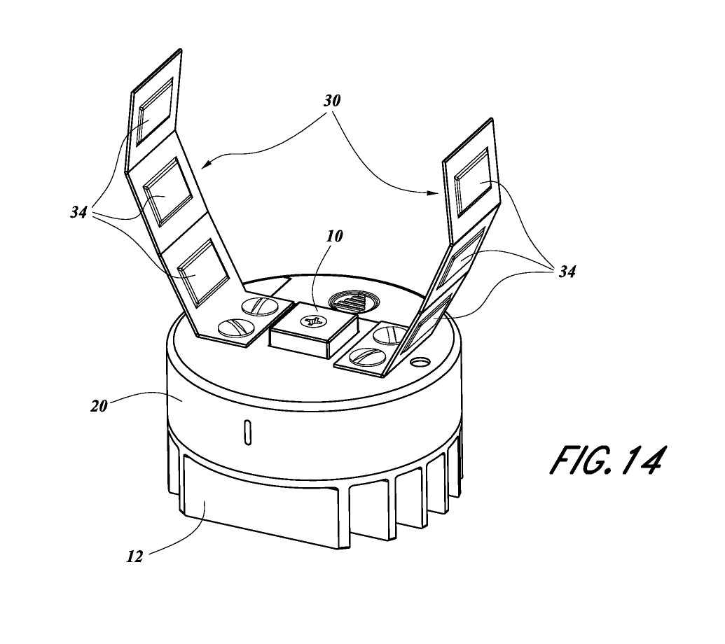

FIGS. 8-14 illustrate another embodiment of an integrated device package 1 that incorporates a TEG device 16. In particular, FIG. 8 is a schematic side sectional view of an integrated device package 1 having a thermoelectric generator device 16 and being connected to a heat source 22, according to another embodiment. FIG. 9 is a schematic, enlarged front sectional view of the integrated device package 1 shown in FIG. 8. FIG. 10 is a schematic, isometric, exploded and inverted view of portions of the integrated device package 1 shown in FIGS. 8 and 9. FIG. 11 is a schematic side elevational view of the integrated device package 1 shown in FIGS. 8-10. FIG. 12 is a top plan view of the integrated device package 1 shown in FIGS. 8-11. FIG. 13 is a schematic side sectional view of an integrated device package 1 connected to a plurality of heat sources 22, 32, according to another embodiment. FIG. 14 is a schematic front and bottom isometric view of the integrated device package 1 connected to a band 30 configured to mount the package to a heat source.

Unless otherwise noted, the features of FIGS. 8-14 may be the same as or generally similar to like-numbered features in FIGS. 1-7. Unlike the embodiment of FIGS. 1-7, as shown in, e.g., FIG. 10, the second thermally conductive element 12 can comprise a standoff structure 12d configured to support the first thermally conductive element 10. As shown in FIGS. 8 and 9, the standoff structure 12d can thermally couple to an upper side of the TEG device(s) 16 and the first element 10 can thermally couple to a lower side of the TEG device (s) 16. The standoff structure 12c can comprise a narrow projection that extends from the floor or external surface of the lateral plate 12a. The standoff structure 12c can be positioned so as to align with the first element 10. As shown in FIG. 10, one or a plurality of fasteners 44 (e.g., screws, bolts, etc.) and washers 45 can be used to connect the first thermally conductive element 10 with the second thermally conductive element 12. As illustrated, the substrate 14 and the electrical components 18 can be disposed in a cavity 12c defined by the second element 12 and the housing 20. In some embodiments, as with the embodiment of FIGS. 1-7, a thermal interface element (such as the thermal interface element 11) can be disposed between the first and second thermally conductive element 10, 12.

Although disclosed in the context of certain embodiments and examples, it will be understood by those skilled in the art that the present invention extends beyond the specifically disclosed embodiments to other alternative embodiments and/or uses and obvious modifications and equivalents thereof. In addition, while several variations have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the present disclosure. It should be understood that various features and aspects of the disclosed embodiments can be combined with, or substituted for, one another in order to form varying modes of the disclosed invention. Thus, it is intended that the scope of the present invention herein disclosed should not be limited by the particular disclosed embodiments described above, but should be determined only by a fair reading of the aspects that follow.

We claim:

1. An integrated device package comprising:
a package substrate;
a thermoelectric generator (“TEG”) device electrically connected to the package substrate, the TEG device configured to convert thermal energy to electrical current; and
a magnet disposed over a front side of the TEG device, the magnet configured to connect to a heat source and to define a thermally conductive pathway between the heat source and the TEG device.

2. The package of claim 1, further comprising a sensor die mounted to the package substrate and in electrical communication with the TEG device, the TEG device configured to provide electrical power to the sensor die.

3. The package of claim 2, further comprising a transmitter mounted to the package substrate and in electrical communication with the sensor die, the transmitter configured to wirelessly transmit data obtained by the sensor to an external device.

4. The package of claim 1, further comprising a heat sink attached to a back side of the TEG device.

5. The package of claim 1, further comprising a thermal interface element disposed between the TEG device and the magnet along the thermally conductive pathway, the thermal interface element configured to reduce transmission of stresses to the front side of the TEG device.

6. The package of claim 1, wherein the package substrate comprises an aperture within which the TEG device is disposed.

7. The package of claim 1, further comprising a band having one or more magnets, the band configured to wrap around at least a portion of the heat source to connect the integrated device package to the heat source.

8. An integrated device package comprising:
a package substrate comprising an aperture;
a thermoelectric generator (“TEG”) device positioned in the aperture and electrically connected to the package substrate, the TEG device configured to convert thermal energy to electrical current; and
a thermally conductive element disposed over a first side of the TEG device, the thermally conductive element configured to define a thermally conductive pathway between a heat source and the TEG device.

9. The package of claim 8, wherein the thermally conductive element comprises a magnet.

10. The package of claim 8, further comprising a sensor die mounted to the package substrate and in electrical communication with the TEG device, the TEG device configured to provide electrical power to the sensor die.

11. The package of claim 10, further comprising a transmitter mounted to the package substrate and in electrical communication with the sensor die, the transmitter configured to wirelessly transmit data obtained by the sensor to an external device.

12. The package of claim 8, further comprising a heat sink attached to a second side of the TEG device.

13. An integrated device package comprising:
a first thermally conductive element;
a second thermally conductive element;
a package substrate disposed between the first and the second thermally conductive elements; and
a thermoelectric generator (“TEG”) device disposed between the first and second thermally conductive elements and electrically connected to the package substrate, the TEG device configured to generate electricity from thermal energy based on a temperature difference between the first and second thermally conductive elements.

14. The package of claim 13, wherein the first thermally conductive element comprises a magnet and the second thermally conductive element comprises a heat sink.

15. The package of claim 13, wherein the package substrate comprising an aperture in which the TEG device is positioned.

16. The package of claim 15, further comprising a second TEG device disposed in a second aperture in the package substrate adjacent the TEG device.

17. The package of claim 13, further comprising a thermal interface element disposed between the TEG device and the first thermally conductive element, the thermal interface element configured to reduce transmission of stresses to a front side of the TEG device.

18. The package of claim 13, further comprising a housing disposed around the first thermally conductive element, the housing mechanically coupled to the second thermally conductive element.

19. The package of claim 13, further comprising an attachment mechanism configured to mechanically connect the integrated device package to a heat source.

20. The package of claim 13, further comprising:
a sensor die mounted to the package substrate and in electrical communication with the TEG device, the TEG device configured to provide electrical power to the sensor die; and
a transmitter mounted to the package substrate and in electrical communication with the sensor die, the transmitter configured to wirelessly transmit data obtained by the sensor to an external device.
